(19) United States
(12) Patent Application Publication
(10) Pub. No.: US 2008/0251237 A1
(43) Pub. Date: Oct. 16, 2008

(54) HEAT DISSIPATION APPARATUS

(75) Inventor: JUI-WEN HUNG, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignee: FOXCONN TECHNOLOGY CO., LTD., Tu-Cheng (TW)

(21) Appl. No.: 11/781,686

(22) Filed: Jul. 23, 2007

(30) Foreign Application Priority Data
Apr. 13, 2007 (CN) 200710074019.0

(51) Int. Cl. H05K 7/20

(52) U.S. Cl. 165/80.3; 361/687; 165/104.33; 361/700

(57) ABSTRACT

A heat dissipation apparatus includes a fin assembly (10) and a centrifugal blower (20). The centrifugal blower includes a housing (22) defining an air outlet (221). An airflow generated by the blower flows through the air outlet to reach the fin assembly to take heat away therefrom. The fin assembly includes a plurality of fins (12) configured for thermally connecting with the heat-generating electronic component to absorb heat therefrom. The fins of the fin assembly are arranged at the air outlet of the centrifugal blower and stacked together. An inner side (12a) of the fin assembly is attached to and in line with the air outlet of the centrifugal blower. An outer side (12b) of the fin assembly is offset from the air outlet a distance along a lateral direction or a vertical direction.

### BACKGROUND OF THE INVENTION

1. Field of the Invention

The present invention relates generally to a heat dissipation apparatus, and more particularly to a heat dissipation apparatus having high heat dissipating efficiency.

2. Description of Related Art

Following the increase in computer processing power that has been seen in recent years, greater emphasis is now being laid on increasing the efficiency and effectiveness of heat dissipation devices. Referring to FIG. 6, a heat dissipation apparatus 50 in accordance with related art includes a centrifugal blower 52 and a fin unit 54 disposed at an air outlet 521 of the centrifugal blower 52. The fin unit 54 includes a plurality of fins 542 which thermally connect with a heat generating electronic component (not shown) to absorb heat therefrom. The centrifugal blower 52 includes a housing 522, a stator (not shown) mounted in the housing 522, and a rotor 523 rotatably disposed around the stator. When the centrifugal blower 52 is activated, the rotor 523 rotates along a counterclockwise direction around the stator to drive an airflow 56 to flow through the fin unit 54 to take away heat therefrom.

In a computer system, the fin unit 54 is located adjacent and perpendicular to a sidewall of a casing of the computer system. The sidewall of the casing defines a plurality of slots therein and includes a plurality of barriers arranged in alternating fashion with the slots. In operation of the heat dissipation apparatus 50, the housing 522 of the centrifugal blower 52 guides the airflow 56 to move through the fins 542 of the fin unit 54 toward the slots of the casing, via which the airflow 56 flows out of the casing. For increasing the heat dissipating area of the heat dissipation apparatus 50, the fin unit 54 should be as large as possible and arranged relative to the slots of the sidewall as close as possible. However, as density of the electronic components arranged in the casing increases, a space of the casing available for receiving the heat dissipation apparatus 50 is limited; thus, the size of the fin unit 54 is limited. Furthermore, the slots and the fin unit 54 usually have a distance therebetween along a lateral direction or a vertical direction. Thus, some of the fins 542 of the fin unit 54 are not exposed to the slots straightly; after flowing through the some of the fins 542, the airflow 56 is blocked by the sidewall of the casing and can not flow out of the casing smoothly through the slots, which in turn decreases the heat dissipating efficiency of the heat dissipation apparatus.

Therefore, it is desirable to provide a heat dissipation apparatus wherein one or more of the foregoing disadvantages may be overcome or at least alleviated.

### SUMMARY OF THE INVENTION

The present invention relates to a heat dissipation apparatus for dissipating heat from a heat-generating electronic component. According to a preferred embodiment of the present invention, the heat dissipation apparatus includes a fin assembly and a centrifugal blower. The centrifugal blower includes a housing defining an air outlet for an airflow generated thereby flowing therethrough to the fin assembly to take heat away therefrom. The fin assembly includes a plurality of fins configured for thermally connecting with the heat-generating electronic component to absorb heat therefrom. The fins of the fin assembly are arranged at the air outlet of the centrifugal blower and stacked together; an inner side of the fin assembly is attached to and in line with the air outlet of the centrifugal blower and an outer side of the fin assembly far from the air outlet of the centrifugal blower is offset vertically or laterally a distance from the air outlet.

Other advantages and novel features of the present invention will become more apparent from the following detailed description of preferred embodiment when taken in conjunction with the accompanying drawings, in which:

### BRIEF DESCRIPTION OF THE DRAWINGS

Many aspects of the present heat dissipation apparatus can be better understood with reference to the following drawings. The components in the drawings are not necessarily drawn to scale, the emphasis instead being placed upon clearly illustrating the principles of the present heat dissipation apparatus. Moreover, in the drawings, like reference numerals designate corresponding parts throughout the several views.

FIG. 1 is an assembled, isometric view of a heat dissipation apparatus according to a preferred embodiment of the present invention;

FIG. 2 is an explored view of the heat dissipation apparatus of FIG. 1;

FIG. 3 shows the heat dissipation apparatus of FIG. 1, but from a bottom aspect;

FIG. 4 is a side view of the heat dissipation apparatus of FIG. 1;

FIG. 5 is an assembled, top plan view of the heat dissipation apparatus according to an alternative embodiment of the present invention; and

FIG. 6 is a top plan view of a heat dissipation apparatus in accordance with related art, with some parts thereof being removed.

### DETAILED DESCRIPTION OF THE INVENTION

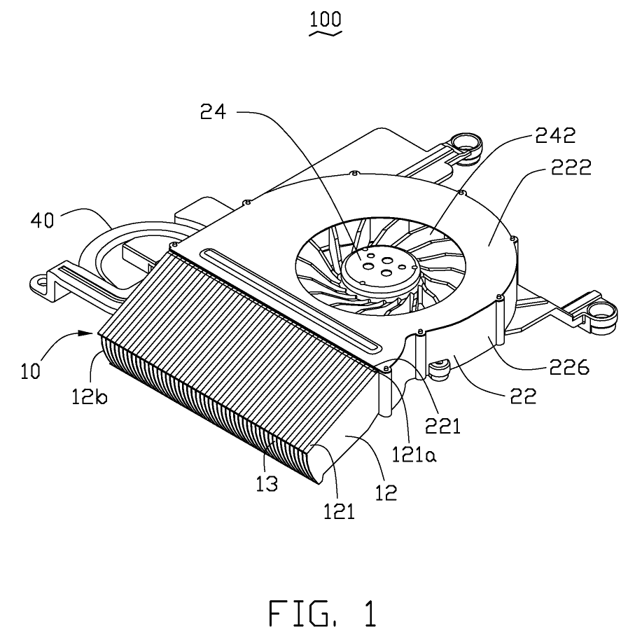

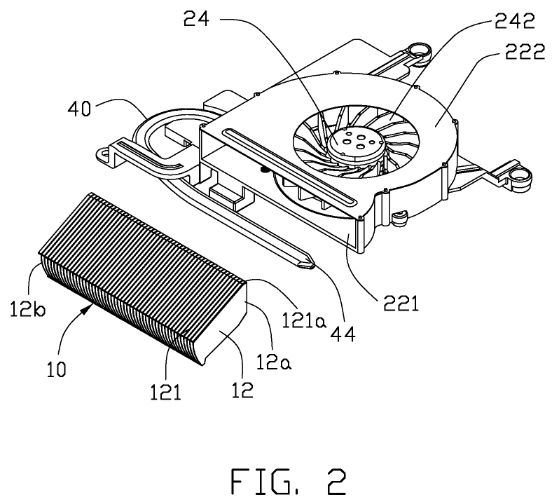

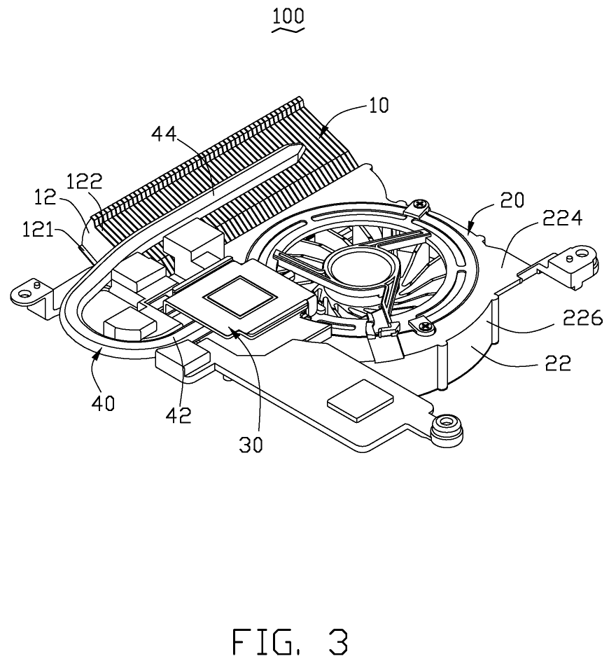

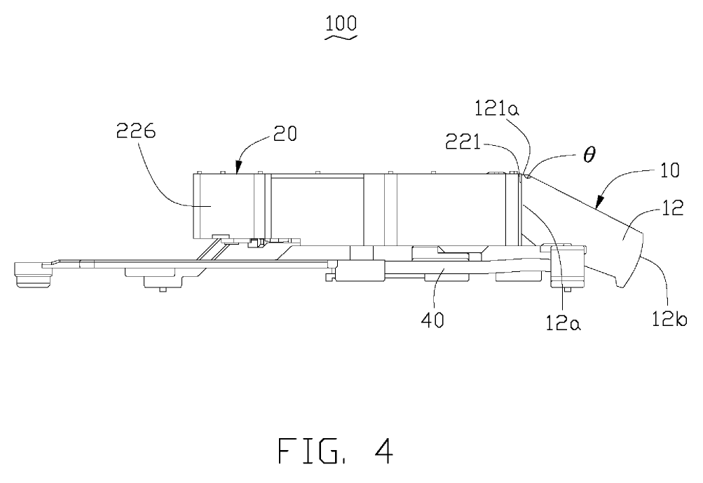

Referring to FIGS. 1 through 4, a heat dissipation apparatus 100 according to a preferred embodiment of the present invention is shown. The heat dissipation apparatus 100 includes a fin assembly 10, a centrifugal blower 20, a base 30 and a heat pipe 40.

The base 30 is thermally attached to a heat-generating electronic component (not shown) such as a CPU of a computer to absorb heat therefrom. The base 30 is made of a material having relatively high heat conductivity, such as copper or aluminum. The heat pipe 40 is curved-shaped, and forms an evaporating section 42 and a condensing section 44 at two opposite ends thereof. The evaporating section 42 and the condensing section 44 are not coplanar and have a level difference therebetween. The evaporating section 42 of the heat pipe 40 is thermally attached to the base 30. The condensing section 44 of the heat pipe 40 is thermally attached to the fin assembly 10, whereby the heat pipe 40 can transfer the heat generated by the heat-generating electronic component via the base 30 to the fin assembly 10 for dissipation.

The centrifugal blower 20 enables to provide an airflow with a high air pressure so as to take the heat away from the fin assembly 10. The centrifugal blower 20 includes a housing 22 having a bottom wall 224, a top wall 222 parallel to the bottom wall 224, and a side wall 226 interconnecting an outer periphery of the top and bottom walls 222, 224. Cooperatively the three walls 222, 224, 226 form the housing 22 with an inner space defined therein. A stator (not shown) is accommodated in the inner space, and a rotor 24 having a plurality of blades 242 is rotatably disposed around the stator. A distance between the side wall 226 and the blades 242 is gradually increased along a rotation direction of the rotor 24 for improving the volumetric flow rate of the airflow. The top wall 222 defines a circular-shaped through hole therein functioning as an air inlet (not labeled) of the centrifugal blower 20. The side wall 226 of the housing 22 defines an opening therein functioning as an air outlet 221 of the centrifugal blower 20. The air outlet 221 is rectangular-shaped and opens to a direction which is perpendicular to that of the air inlet.

The fin assembly 10 is disposed at the air outlet 221 of the centrifugal blower 20, and includes a plurality of stacked fins 12. A plurality of channels 13 communicating with the air outlet 221 are defined between the fins 12. Each fin 12 is rectangular-shaped. A pair of hems 121, 122 bend from top and bottom ends of each fin 12, respectively. The hems 121, 122 of each fin 12 abut an adjacent fin 12 and thus cooperatively form top and bottom surfaces (not labeled) of the fin assembly 10. Each fin 12 of the fin assembly 10 forms a connecting portion 121a at an inner side 12a thereof, near a top end of the inner side 12a. The connecting portion 121a is horizontal. The top surface (not labeled) of the fin assembly 12 is declinedly extended from the connecting portions 121a with an obtuse angle θ defined therebetween.

During assembly, the base 30 is fixedly connected with the bottom wall 224 of the centrifugal blower 20. The evaporating section 42 of the heat pipe 40 is mounted between the bottom wall 224 and the base 30, and the condensing section 44 of the heat pipe 40 attaches to the bottom surface of the fin assembly 10. The fin assembly 10 is assembled with the centrifugal blower 20; the inner side 12a of the fin assembly 10 is attached to and in line with the air outlet 221 of the centrifugal blower 20, by having the connecting portions 121a soldered to an inner side of the top wall 222 of the centrifugal blower 20. Thus, the fin assembly 10 and the centrifugal blower 20 are assembled securely together. The connecting portions 121a are parallel to the top wall 222 of the centrifugal blower 20. The fin assembly 10 is thus arranged declined relative to the air outlet 221 of the centrifugal blower 20. The top surface of the fin assembly 10 and the top wall 222 of the centrifugal blower 20 also define an obtuse angle therebetween, which is equal to the obtuse angle θ between the connecting portions 121a and the top surface of the fin assembly 10. A level of the fin assembly 10 is gradually reduced from the inner side 12a to an outer side 12b of the fin assembly 10 far from the air outlet 221, in which the top and bottom ends of the inner side 12a of the fin assembly 10 are respectively substantially coplanar with the top and bottom walls 222, 224 of the centrifugal blower 20, and the top and bottom ends of the outer side 12b of the fin assembly 10 are respectively lower than the top and bottom walls 222, 224 of the centrifugal blower 20. In other words, the outer side 12b of the fin assembly 10 is offset vertically a distance from the air outlet 221 of the blower 20.

During operation, the heat-generating electronic component is arranged under the base 30. Working fluid contained in the evaporating section 42 of the heat pipe 40 absorbs the heat generated by the heat-generating electronic component via the base 30 and evaporates into vapor. The vapor moves to the condensing section 44. The vapor is cooled and condensed at the condensing section 44. The condensed working fluid flows back to the evaporating section 42 to begin another thermal cycle. The heat of the heat-generating electronic device is thus released to the fin assembly 10 through the heat pipe 40 almost immediately. The airflow generated by the centrifugal blower 20 flows through the air outlet 221 and then through the channels 13 of the fin assembly 10. As the airflow generated by the centrifugal blower 20 passes through the channels 13 of the fin assembly 10, the heat of the fin assembly 10 is taken away by the airflow to surrounding atmosphere.

In the present invention, as the fin assembly 10 is arranged declinedly relative to the air outlet 221, a flowing direction of the airflow can be changed after flowing through the air outlet 221. Thus if the slots defined in a casing which receives the heat dissipation apparatus 100 and the heat-generating electronic component therein are not in line with the air outlet 221 of the centrifugal blower 20, the present invention can resolve the problem by having the outer side 12b of the fin assembly 10 extended to be located adjacent to and facing straight to the slots, whereby the flowing direction of the airflow after flowing through the air outlet 221 is adjusted to flow directly to the slots of the casing. Thus, the airflow can flow out the casing through the slots easily. As shown in this embodiment, the inner side 12a of the declined fin assembly 10 attached to the centrifugal blower 20 is higher than the outer side 12b of the fin assembly 10, which can be used in the situation that the slots of the casing are located at a level lower than that of the air outlet 221 along the vertical direction. Alternatively, the outer side 12b of the inclined fin assembly 10 can be at a level higher than that the inner side 12a; in this situation, the fin assembly 10 can be used in the casing which has the slots at a level higher than that of the air outlet 221 of the centrifugal blower 20. As the fin assembly 10 can be slanted in a direction for accommodating the flowing direction of the airflow according to the position of the slots of the casing, the airflow blocked by the casing is avoided and thus the airflow can flow out of the casing easily and timely, which finally increases the heat dissipating efficiency of the heat dissipation apparatus.

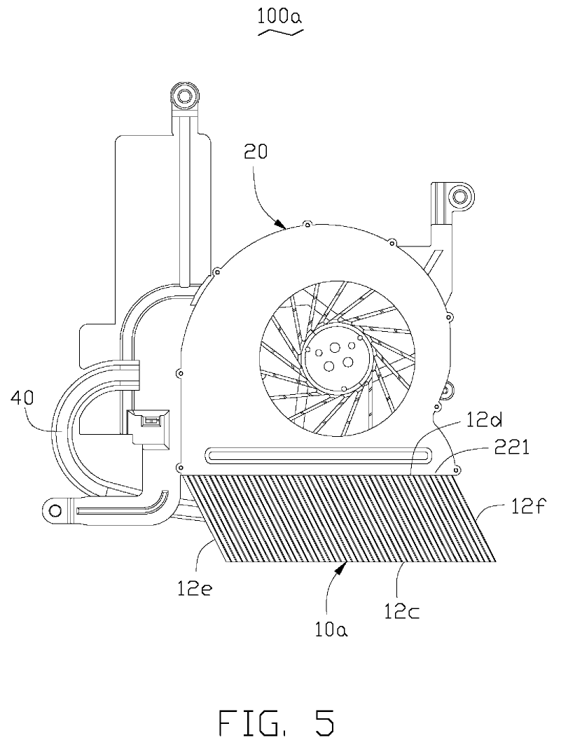

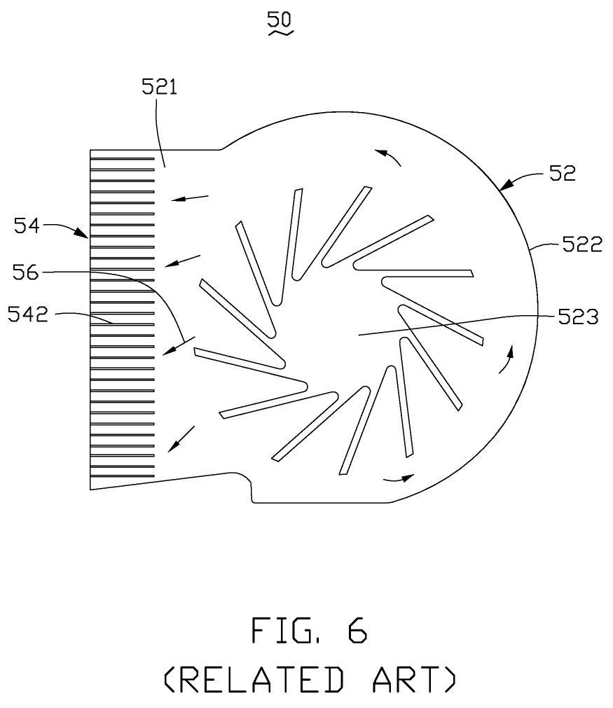

FIG. 5 shows a heat dissipation apparatus 100a according to an alternative embodiment of the present invention. Also the heat dissipation apparatus 100a has a fin assembly 10a being arranged at an air outlet 221 of the centrifugal blower 20. The difference between the second embodiment and the first embodiment is that the outer and inner sides 12c, 12d of the fin assembly 10a have the same level along the vertical direction, but are spaced from each other a distance along a lateral direction. The inner side 12d of the fin assembly 10a is located on the left of the outer side 12c of the fin assembly 10a. The left and right sides 12e, 12f of the fin assembly 10a are inclined relative to the horizontal direction, rather than perpendicular thereto as the fin unit 54 of the related art of FIG. 6. Thus when the slots of the casing is arranged on a right of the air outlet 221 of the centrifugal blower 20, the fin assembly 10a can change the flowing direction of the airflow to a right direction according to the position of the slots of the casing. It is to be understood that the inner side 12d of fin assembly 10a can be on the right of the outer side 12c of the fin assembly 10a thus to guide the airflow flowing to a left direction when the slots of the casing are arranged on a left of the air outlet 221.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat dissipation apparatus configured for dissipating heat from a heat-generating electronic component, comprising:
a fin assembly comprising a plurality of fins configured for thermally connecting with the heat-generating electronic component to absorb heat therefrom; and
a centrifugal blower comprising a housing defining the air outlet for an airflow generated by the centrifugal blower to flow therethrough to reach the fin assembly thereby taking heat away from the fin assembly;
wherein the fins of the fin assembly are arranged at an air outlet of the centrifugal blower and stacked together, an inner side of the fin assembly being attached to and in line with the air outlet and an outer side thereof which is far from the air outlet of the centrifugal blower being offset from the air outlet a distance along one of a lateral direction and a vertical direction.

2. The heat dissipation apparatus as described in claim 1, further comprising a base being used for thermally connecting with the heat-generating electronic component, and a heat pipe having an evaporating section attaching to the base and a condensing section attaching to the fin assembly.

3. The heat dissipation apparatus as described in claim 2, wherein the heat pipe is curve-shaped, the evaporating and condensing sections of the heat pipe being at different levels.

4. The heat dissipation apparatus as described in claim 1, wherein the inner side of the fin assembly is higher than the outer side of the fin assembly along the vertical direction.

5. The heat dissipation apparatus as described in claim 1, wherein the inner side of the fin assembly is lower than the outer side of the fin assembly along the vertical direction.

6. The heat dissipation apparatus as described in claim 1, wherein the inner side of the fin assembly is arranged on the left of the outer side of the fin assembly along the lateral direction.

7. The heat dissipation apparatus as described in claim 1, wherein the inner side of the fin assembly is arranged on the right of the outer side of the fin assembly along the lateral direction.

8. The heat dissipation apparatus as described in claim 1, wherein each of the fins forms a connecting portion abutting an inner side of the housing of the centrifugal blower.

9. A heat dissipation apparatus for dissipating heat generated by an electronic component, comprising:
a blower having an air outlet through which an airflow generated by the blower leaves the blower;
a fin assembly adapted for thermally connecting with the electronic component, having a plurality of fins stacked together, wherein the fin assembly has an inner side attached to and in line with the air outlet of the blower and an outer side distant from the air outlet, the outer side being offset from the air outlet a distance along one of vertical and lateral directions.

10. The heat dissipation apparatus as described in claim 9 further comprising a heat pipe having a condensing section connecting with the fin assembly and an evaporating section adapted for thermally connecting with the electronic component.

11. The heat dissipation apparatus as described in claim 10 further comprising a base connecting with the evaporating section of the heat pipe, the base being adapted for thermally connecting with the electronic component.
